(19) United States
(12) Patent Application Publication
(10) Pub. No.: US 2026/0136663 A1
(43) Pub. Date: May 14, 2026

(54) SEMICONDUCTOR DEVICES

(71) Applicant: Samsung Electronics Co., Ltd., Suwon-si (KR)

(72) Inventors: SUBIN CHOI, Suwon-si (KR); BYUNGSUNG KIM, Suwon-si (KR); SUNGHO PARK, Suwon-si (KR); JISOO PARK, Suwon-si (KR); PANJAE PARK, Suwon-si (KR)

(21) Appl. No.: 19/269,355

(22) Filed: Jul. 15, 2025

(30) Foreign Application Priority Data
Nov. 12, 2024 (KR) 10-2024-0159920

(51) Int. Cl. H10D 84/90; H10D 89/10

(52) U.S. Cl. CPC H10D 84/974; H10D 84/922; H10D 84/953; H10D 89/10

(57) ABSTRACT

A semiconductor device includes a merged cell including first and second active patterns extending in a first direction and including a first p-type transistor on the first active pattern and a first n-type transistor on the second active pattern; a first half-cell adjacent to the merged cell in a second direction and including a third active pattern; a second half-cell adjacent to the merged cell in the second direction and including a fourth active pattern; and a logic circuit element on at least one of the third active pattern or the fourth active pattern. The first and second half-cells each have a second cell height, less than a first cell height of the merged cell. Each of the third and fourth active patterns has a second width, less than a first width of each of the first and second active patterns.

### CROSS-REFERENCE TO RELATED APPLICATIONS

This application claims benefit of priority to Korean Patent Application No. 10-2024-0159920 filed on Nov. 12, 2024 in the Korean Intellectual Property Office, the disclosure of which is incorporated herein by reference in its entirety.

### BACKGROUND OF THE INVENTION

The present disclosure relates to semiconductor devices.

As the demand for high performance, high speed, and/or multifunctionality, or the like of semiconductor devices increases, a degree of integration of semiconductor devices is also increasing. As a degree of integration of semiconductor devices increases, operating characteristics of the semiconductor devices may deteriorate. Accordingly, various methods are being studied to form semiconductor devices with better performance while overcoming limitations of a degree of integration of semiconductor devices. In order to overcome limitations of the operating characteristics due to scaling down, efforts are being made to develop a semiconductor device including a transistor having a three-dimensional (3D) channel structure.

### SUMMARY OF THE INVENTION

Aspects of the present disclosure provide semiconductor devices that are advantageous for a high degree of integration while maintaining operating characteristics.

According to some aspects of the present disclosure, a semiconductor device includes a merged cell including a first active pattern and a second active pattern extending in a first direction and spaced apart from each other in a second direction intersecting the first direction, the merged cell further including a first p-type transistor on the first active pattern and a first n-type transistor on the second active pattern; a first half-cell adjacent to the first active pattern of the merged cell in the second direction and including a third active pattern extending in the first direction; a second half-cell adjacent to the second active pattern of the merged cell in the second direction and including a fourth active pattern extending in the first direction; and a logic circuit element on at least one of the third active pattern or the fourth active pattern, wherein the merged cell has a first cell height in the second direction, and the first and second half-cells each have a second cell height in the second direction that is less than the first cell height, and wherein each of the first and second active patterns has a first width in the second direction, and each of the third and fourth active patterns has a second width in the second direction that is less than the first width.

According to some aspects of the present disclosure, a semiconductor device includes first to third rows each including a first conductivity type active pattern and a second conductivity type active pattern extending in a first direction and arranged in a second direction intersecting the first direction, wherein the first and second conductivity type active patterns of the second row are adjacent to the first conductivity type active pattern of the first row and the second conductivity type active pattern of the third row, respectively; a merged cell in the second row and extending in a first region of each of the first and third rows adjacent to the second row, the merged cell including a first merged active pattern in which the first conductivity type active patterns of the first and second rows are merged, and a second merged active pattern in which the second conductivity type active patterns of the second and third rows are merged; a first half-cell overlapping the merged cell in the second direction and extending in a second region of the first row, the first half-cell including the second conductivity type active pattern of the first row; and a second half-cell overlapping the merged cell in the second direction and extending in a second region of the third row, the second half-cell including the first conductivity type active pattern of the third row, wherein the merged cell includes a first conductivity type transistor on the first merged active pattern and a second conductivity type transistor on the second merged active pattern, and wherein at least one of the first half-cell or the second half-cell includes a transistor or a capacitor on the second conductivity type active pattern of the first row or the first conductivity type active pattern of the third row.

According to some aspects of the present disclosure, a semiconductor device includes a merged cell including a first active pattern and a second active pattern extending in a first direction and spaced apart from each other in a second direction intersecting the first direction, the merged cell further including a first p-type transistor on the first active pattern and a first n-type transistor on the second active pattern; a first half-cell adjacent to the first active pattern of the merged cell in the second direction and including a third active pattern extending in the first direction, the first half-cell further including a second n-type transistor on the third active pattern; and a second half-cell adjacent to the second active pattern of the merged cell in the second direction and including a fourth active pattern extending in the first direction, the second half-cell further including a second p-type transistor on the fourth active pattern, wherein the merged cell has a first cell height in the second direction, and the first and second half-cells each have a second cell height in the second direction that is less than the first cell height, and wherein each of the first and second active patterns has a first width in the second direction, and each of the third and fourth active patterns has a second width in the second direction that is less than the first width.

### BRIEF DESCRIPTION OF DRAWINGS

The above and other aspects, features, and advantages of the present disclosure will be more clearly understood from the following detailed description, taken in conjunction with the accompanying drawings, in which:

FIGS. 1A and 1B are plan views illustrating a semiconductor device (before/after application of an interconnection structure) according to some embodiments.

FIG. 2 is a plan view illustrating a basic cell layout introduced into the semiconductor device of FIGS. 1A and 1B.

FIG. 3 is a cross-sectional view of the semiconductor device illustrated in FIG. 1B, taken along line I-I′.

FIG. 4 is a cross-sectional view of the semiconductor device illustrated in FIG. 1B, taken along line II-II′.

FIGS. 5A and 5B are cross-sectional views of the semiconductor device illustrated in FIG. 1B, taken along lines III1-III1′ and III2-III2′, respectively.

FIGS. 6A and 6B are cross-sectional views illustrating a semiconductor device according to some embodiments.

FIGS. 7A and 7B are schematic plan views illustrating a cell layout of a semiconductor device according to some embodiments.

FIGS. 8A and 8B are schematic plan views illustrating a semiconductor device (before/after application of an interconnection structure) according to some embodiments.

FIGS. 9A and 9B are cross-sectional views of the semiconductor device illustrated in FIG. 8B, taken along lines I1-I1′ and I2-I2′, respectively.

FIG. 10 is a cross-sectional view of the semiconductor device illustrated in FIG. 8B, taken along line II-II′.

FIG. 11 is a schematic plan view illustrating a semiconductor device according to some embodiments.

FIG. 12 is a schematic plan view illustrating a cell layout of a semiconductor device according to some embodiments.

### DETAILED DESCRIPTION

Hereinafter, various example embodiments will be described in detail with reference to the attached drawings.

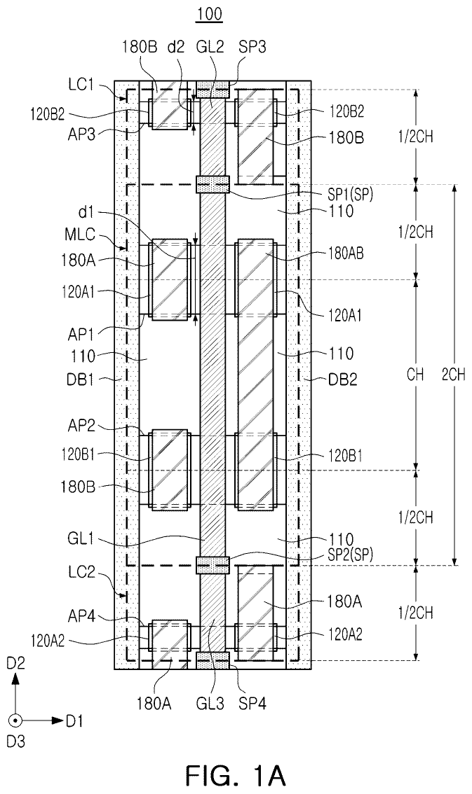

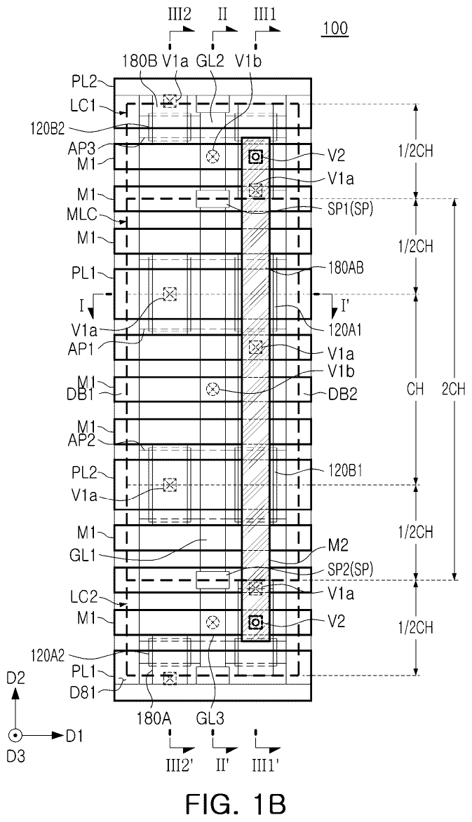

FIGS. 1A and 1B are plan views illustrating a semiconductor device according to some embodiments, and illustrate the semiconductor device before and after application of an interconnection structure, respectively.

Referring to FIGS. 1A and 1B, a semiconductor device 100 according to some embodiments may include a first half-cell LC1 and a second half-cell LC2, and a merged cell MLC between the first and second half-cells LC1 and LC2. The merged cell MLC may be disposed between the first half-cell LC1 and the second half-cell LC2 to overlap the first and second half-cells LC1 and LC2 in a second direction D2.

The merged cell MLC according to some embodiments may include a first active pattern AP1 and a second active pattern AP2, extending in a first direction D1 and spaced apart in the second direction D2. In some embodiments, the merged cell MLC may include a first conductivity type (e.g., p-type) transistor on the first active pattern AP1 and a second conductivity type (e.g., n-type) transistor on the second active pattern AP2. As used herein, the terms “first conductivity type” and “second conductivity type” are used to indicate either n-type or p-type, where the first and second conductivity types are different from each other. Thus, if a first region of a device has a first conductivity type and a second region of the device has a second conductivity type, this means either that the first region has n-type conductivity and the second region has p-type conductivity or, alternatively, that the first region has p-type conductivity and the second region has n-type conductivity.

Each of the first and second half-cells LC1 and LC2 may include an active pattern. The first half-cell LC1 may include a third active pattern AP3 extending in the first direction D1, and the second half-cell LC2 may include a fourth active pattern AP4 extending in the first direction D1. The semiconductor device 100 according some embodiments may include a logic circuit element, such as a transistor or a capacitor, in at least one of the first and second half-cells LC1 and LC2. In some embodiments, the first half-cell LC1 may include a second conductivity type (e.g., n-type) transistor on the third active pattern AP3, and the second half-cell LC2 may include a first conductivity type (e.g., p-type) transistor on the fourth active pattern AP4. The first direction D1 and the second direction D2 may intersect each other. For example, the first direction D1 and the second direction D2 may be parallel to upper surfaces of the first to fourth active patterns AP1, AP2, AP3, and AP4. In some embodiments, the first direction D1 and the second direction D2 may be perpendicular to each other.

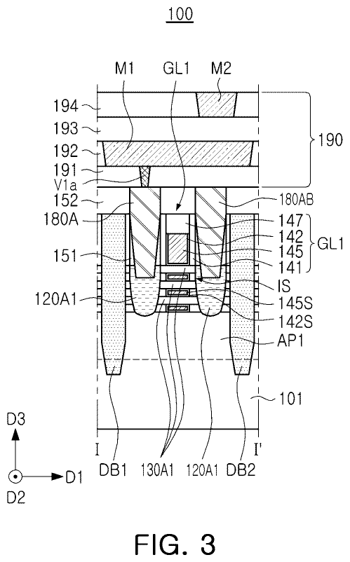

Transistors introduced in the semiconductor device 100 according to some embodiments may include a transistor having a gate-all-around (GAA) structure and including a plurality of channel patterns 130A and 130B stacked in a vertical direction (e.g., a third direction D3). This will be described in greater detail below with reference to FIGS. 3, 4, 5A, and 5B.

In some embodiments, each of the first and second active patterns AP1 and AP2 of the merged cell MLC may have a first width d1 (e.g., in the second direction D2), and each of the third and fourth active patterns AP3 and AP4 may have a second width d2 (e.g., in the second direction D2), smaller than (i.e., less than) the first width d1. The merged cell MLC may have a first cell height 2CH (e.g., in the second direction D2), and the first and second half-cells LC1 and LC 2 may have a second cell height ½CH (e.g., in the second direction D2), lower than (i.e., less than) the first cell height 2CH.

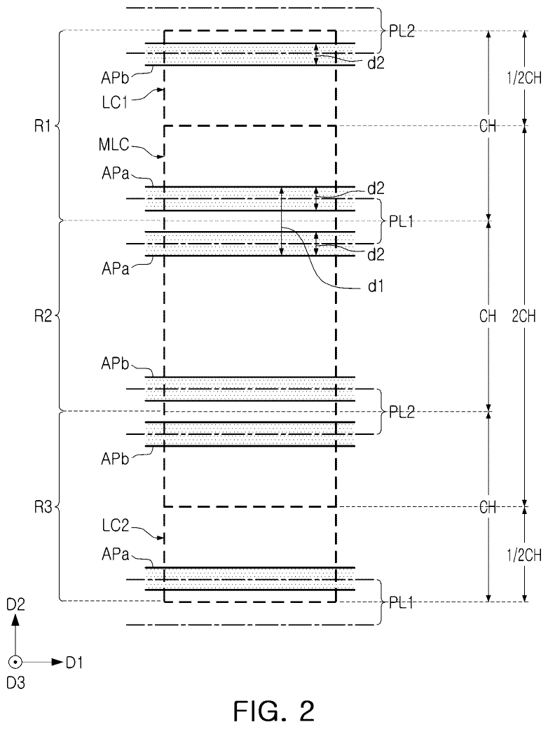

The merged cell MLC and the first and second half-cells LC1 and LC2 can be understood as cells obtained from a basic cell layout illustrated in FIG. 2. FIG. 2 is a plan view illustrating a basic cell layout introduced into the semiconductor device 100 of FIGS. 1A and 1B.

Referring to FIG. 2, a basic cell layout may include basic cells aligned in the second direction D2 in first to third rows R1, R2, and R3, and the basic cells may have the same cell height CH as each other. In some embodiments, the first to third rows R1, R2, and R3 may each have the same row height (e.g., in the second direction D2). For example, the row height of each of the first to third rows R1, R2, and R3 may be equal to the cell height CH. A first power line PL1 and a second power line PL2 for supplying voltage may be disposed on each boundary of the first to third rows R1, R2, and R3, i.e., on a boundary of the basic cells, and the first power line PL1 and the second power line PL2 extend in the first direction D1, and may be disposed alternately in the second direction D2. The basic cells respectively located in the first to third rows R1, R2, and R3 may include a first conductivity type active pattern APa and a second conductivity type active pattern APb, extending in the first direction D1 and spaced apart in the second direction D2.

The first conductivity type active pattern APa and the second conductivity type active pattern APb may be provided as active patterns for transistors of different types (p-type or n-type). For example, the first conductivity type active pattern APa may be an active pattern for a p-type transistor, and the second conductivity type active pattern APb may be an active pattern for an n-type transistor.

In some embodiments, the first conductivity type active pattern APa and the second conductivity type active pattern APb of the first to third rows R1, R2, and R3 may have the same width d2 (e.g., in the second direction D2). The first and second conductivity type active patterns APa and APb of the second row R2 may be located adjacent to the first conductivity type active pattern APa of the first row R1 and the second conductivity type active pattern APb of the third row R3, respectively.

The merged cell MLC according to some embodiments can be understood as being disposed across the second row R2 and adjacent regions of the first row R1 and the third row R3. As illustrated in FIGS. 1A and 1B, the first active pattern AP1 of the merged cell MLC may be a first merged active pattern in which adjacent first conductivity type active patterns APa of the first and second rows R1 and R2 of FIG. 2 are merged. Similarly, the second active pattern AP2 of the merged cell MLC may be a second merged active pattern in which adjacent second conductivity type active patterns APb of the second and third rows R2 and R3 of FIG. 2 are merged. Therefore, the first width d1 of each of the first and second active patterns AP1 and AP2 may be greater than (i.e., more than) twice the second width d2 of each of the third and fourth active patterns AP3 and AP4.

The first half-cell LC1 and the second half-cell LC2 may be respectively disposed in remaining regions of the first row R1 and the third row R3. As illustrated in FIGS. 1A and 1B, the first half-cell LC1 may overlap the merged cell MLC in the second direction D2, and the second conductivity type active pattern APb of the first row R1 (see FIG. 2) may be provided as the third active pattern AP3 of the first half-cell LC1. Similarly, the second half-cell LC2 may overlap the merged cell MLC in the second direction D2, and the first conductivity type active pattern Apa of the third row R3 (see FIG. 2) may be provided as the fourth active pattern AP4 of the second half-cell LC2 (see FIGS. 1A and 1B). The third and fourth active patterns AP3 and AP4 may have the second width d2 corresponding to the width d2 of the first and second conductivity type active patterns Apa and Apb of FIG. 2, respectively.

In addition, the merged cell MLC may have a first cell height 2CH (e.g., in the second direction D2) corresponding to a sum of heights CH of two rows, and each of the first and second half-cells LC1 and LC2 may have a second cell height ½CH (e.g., in the second direction D2) corresponding to a height of half a row. In other words, the merged cell MLC may have the first cell height 2CH that is twice the row height (e.g., CH) of each of the first to third rows R1, R2, and R3, and each of the first and second half-cells LC1 and LC2 may have the second cell height ½CH that is half the row height of each of the first to third rows R1, R2, and R3. The first cell height 2CH may be four times the second cell height ½CH. In some embodiments, a width of each of the first and second half-cells LC1 and LC2 (e.g., in the first direction D1) may be substantially equal to a width of the merged cell MLC (e.g., in the first direction D1).

As described above, the merged cell MLC according to some embodiments may include a first p-type transistor on the first active pattern AP1 and a first n-type transistor on the second active pattern AP2. In addition, the first half-cell LC1 may include a second n-type transistor on the third active pattern AP3, and the second half-cell LC2 may include a second p-type transistor on the fourth active pattern AP4. The second n-type transistor and the second p-type transistor may be connected (e.g., electrically connected) by a second interconnection line M2 extending in the second direction D2, to form a complementary metal-oxide-semiconductor (CMOS) circuit.

In this manner, according to some embodiments, the first and second half-cells LC1 and LC2 on which one active pattern (AP3 and AP4) is disposed, respectively, may be utilized as active cells. This will be described in greater detail below with reference to FIGS. 3, 4, 5A, and 5B along with FIGS. 1A and 1B.

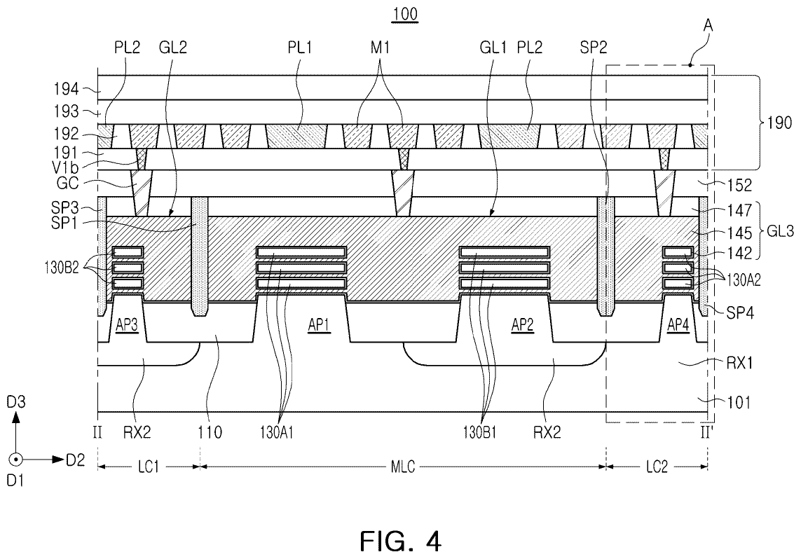

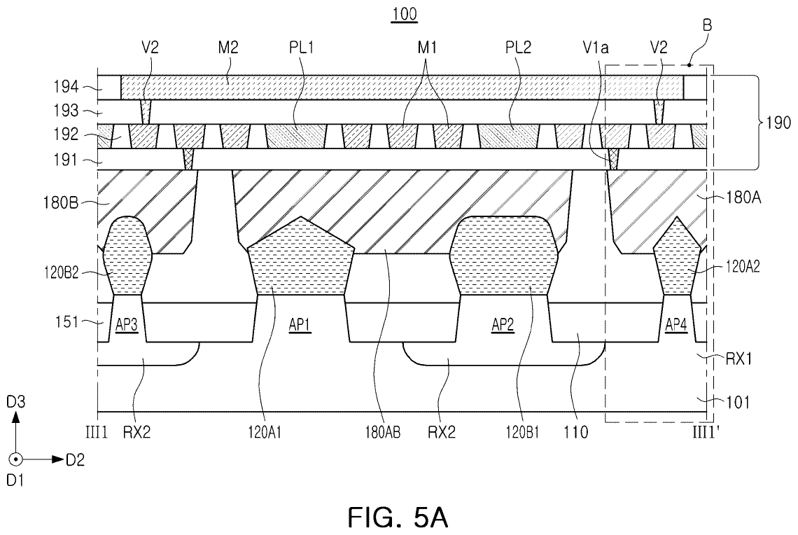

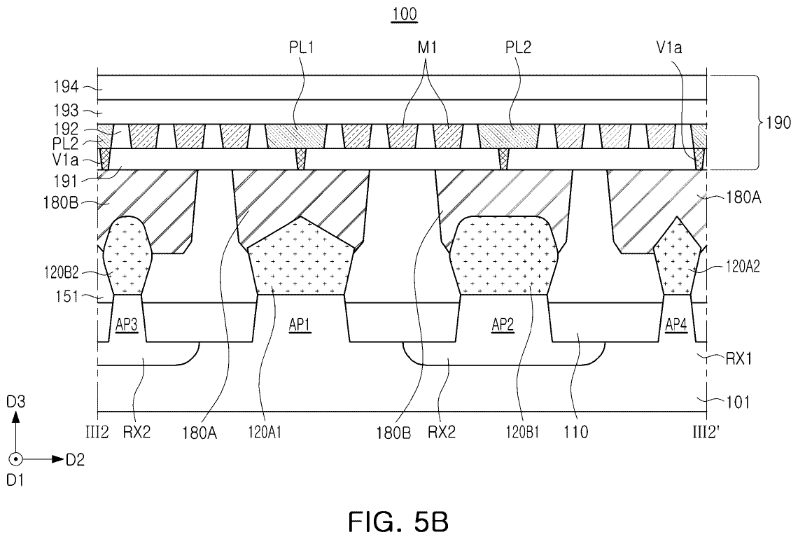

FIG. 3 is a cross-sectional view of the semiconductor device illustrated in FIG. 1B, taken along line I-I′. FIG. 4 is a cross-sectional view of the semiconductor device illustrated in FIG. 1B, taken along line II-II′. FIGS. 5A and 5B are cross-sectional views of the semiconductor device illustrated in FIG. 1B, taken along lines III1-III1′ and III2-III2′, respectively.

Referring to FIGS. 3, 4, 5A, and 5B along with FIGS. 1A and 1B, the semiconductor device 100 according to some embodiments may include the first half-cell LC1 and the second half-cell LC2, disposed on a substrate 101, and the merged cell MLC disposed between the first half-cell LC1 and the second half-cell LC2. Each of the first and second half-cells LC1 and LC2 and the merged cell MLC, according to some embodiments, may have transistors configuring a logic circuit disposed therein, and the transistors according to some embodiments may include a transistor having a gate-all-around (GAA) structure and including the plurality of channel patterns 130A and 130B stacked in the vertical direction (e.g., the third direction D3).

Hereinafter, a transistor structure implemented in each cell of the semiconductor device 100 according to some embodiments will be described in detail with reference to FIGS. 3, 4, 5A, and 5B.

First, the substrate 101 may include, for example, a semiconductor such as Si or Ge, or a compound semiconductor such as SiGe, SiC, GaAs, InAs, or InP. In another example, the substrate 101 may have a silicon-on-insulator (SOI) structure. The substrate 101 may include a first active region RX1 and a second active region RX2. In some embodiments, the first and second active regions RX1 and RX2 may include a specific type (e.g., p-type or n-type) impurity region. For example, the first active region RX1 may be provided by the substrate 101 doped with a p-type impurity, and the second active region RX2 may include a well doped in a portion of the substrate 101.

Referring to FIGS. 4, 5A, and 5B, the first active region RX1 and the second active region RX2 may be alternately disposed in the second direction D2. For example, the first active region RX1 may be provided as a P-MOSFET (PMOS) region, and the second active region RX2 may be provided as an N-MOSFET (NMOS) region. The merged cell MLC may include the first active region and the second active region disposed in the second direction D2, and the first half-cell LC1 and the second half-cell LC2 may include the second active region RX2 and the first active region RX1, respectively.

In the first active region RX1, the first and fourth active patterns AP1 and AP4 extending in the first direction D1 may be disposed, respectively, and in the second active region RX2, the second and third active patterns AP2 and AP3 extending in the first direction D1 may be disposed. In this case, the first and second active patterns AP1 and AP2 may be merged active patterns having the first width d1, respectively, and the third and fourth active patterns AP3 and AP4 may be active patterns having the second width d2, smaller than the first width d1.

Each of the first to fourth active patterns AP1, AP2, AP3, and AP4 may have a fin-shaped structure in which a portion protrudes from a device isolation layer 110. The device isolation layer 110 may be disposed on the substrate 101 to define the first to fourth active patterns AP1, AP2, AP3, and AP4. For example, the device isolation layer 110 may include silicon oxide or an insulating material of a silicon oxide series. In some embodiments, the device isolation layer 110 further may include a ‘deep trench isolation (DTI)’ defining the first and second active regions (RX1, RX2), and in this case, a portion of the device isolation layer 110 defining the first to fourth active patterns AP1, AP2, AP3, and AP4 may be referred to as a ‘shallow trench isolation (STI)’.

Referring to FIGS. 1A, 1B, and 3, the first and second half-cells LC1 and LC2 and the merged cell MLC on the substrate 101 may be defined by first and second isolation structures DB1 and DB2. The first and second isolation structures DB1 and DB2 may define lengths of the first to fourth active patterns AP1, AP2, AP3, and AP4 in the first direction D1. The first isolation structure DB1 and the second isolation structure DB2 may extend in the second direction D2 similarly to gate lines GL1, GL2, and GL3, and may be disposed at the same pitch together with the gate lines GL1, GL2, and GL3 in the first direction D1. The first and second isolation structures DB1 and DB2 may be lower than lower ends of source/drain patterns (e.g., 120A1 in FIG. 3) in the third direction D3. In some embodiments, lower ends of the first and second isolation structures DB1 and DB2 may extend to have a depth, lower than lower ends of the active patterns (e.g., AP1 in FIG. 3) in the third direction D3. Upper surfaces of the first and second isolation structures DB1 and DB2 may be substantially coplanar with an upper surface of a gate capping layer 147 and upper surfaces of gate spacers 141. The firsecond second isolation structures DB1 and DB2 may include a different material from the device isolation layer 110. For example, the first and second isolation structures DB1 and DB2 may include silicon nitride. The third direction D3 may intersect the first direction D1 and the second direction D2. For example, the third direction D3 may be perpendicular to upper surfaces of the first to fourth active patterns AP1, AP2, AP3, and AP4.

As described above, the merged cell MLC may have the first active pattern AP1 and the second active pattern AP2, and the first half-cell LC1 and the second half-cell LC2 may have the third active pattern AP3 and the fourth active pattern AP4, respectively.

Referring to FIGS. 3 and 4, first channel patterns 130A1 may be vertically stacked (e.g., in the third direction D3) while being spaced apart from each other on one region of the first active pattern AP1, and second channel patterns 130B1 may be vertically stacked (e.g., in the third direction D3) while being spaced apart from each other on one region of the second active pattern AP2. Similarly, third channel patterns 130B2 may be vertically stacked (e.g., in the third direction D3) while being spaced apart from each other on one region of the third active pattern AP3, and fourth channel patterns firsecond 130A2 may be vertically stacked (e.g., in the third direction D3) while being spaced apart from each other on one region of the fourth active pattern AP4.

The first width d1 of the first and second active patterns AP1 and AP2 may be larger than the second width d2 of the third and fourth active patterns AP3 and AP4, and proportionally, each of the first and second channel patterns 130A1 and 130B1 may have a width (e.g., in the second direction D2), greater than a width of each of the third and fourth channel patterns 130B2 and 130A2. For example, the width of each of the first and second channel patterns 130A1 and 130B1 may be greater than twice the width of each of the third and fourth channel patterns 130B2 and 130A2. In this manner, a transistor located in the merged cell MLC may have an extended effective channel width.

In some embodiments, each of the first to fourth channel patterns 130A1, 130B1, 130B2, and 130A2 may include three semiconductor patterns sequentially stacked. For example, the semiconductor patterns may include silicon (Si), germanium (Ge), or silicon-germanium (SiGe). The three semiconductor patterns are illustrated as three, but the number and shapes thereof may be changed.

Referring to FIGS. 1A, 1B, 3, 5A, and 5B, first to fourth source/drain patterns 120A1, 120B1, 120B2, and 120A2 may be provided on the first to fourth active patterns AP1, AP2, AP3, and AP4, respectively.

In the merged cell MLC, a pair of first source/drain patterns 120A1 may be disposed on the first active pattern AP1 to be connected to both (i.e., opposite) sides of the first channel patterns 130A1 in the first direction D1, and a pair of second source/drain patterns 120B1 may be disposed on the second active pattern AP2 to be connected to both sides of the second channel patterns 130B1 in the first direction D1, respectively.

In the first half-cell LC1, a pair of third source/drain patterns 120B2 may be disposed on the third active pattern AP3 to be connected to both sides of the third channel patterns 130B2 in the first direction D1, respectively. Similarly, in the second half-cell LC2, a pair of fourth source/drain patterns 120A2 may be disposed on the fourth active pattern AP4 to be connected to both sides of the fourth channel patterns 130A2 in the first direction D1, respectively.

In some embodiments, the first and fourth source/drain patterns 120A1 and 120A2 may include epitaxial layers doped with impurities of the same first conductivity type (e.g., p-type), and the second and third source/drain patterns 120B1 and 120B2 may include epitaxial layers doped with impurities of the same second conductivity type (e.g., n-type). For example, the epitaxial layer doped with the p-type impurity may include silicon germanium, and may include at least one p-type impurity of B, C, Al, Ga, or In. For example, a concentration of germanium may be 40 atm % to 70 atm %. The epitaxial layer doped with the n-type impurity may include silicon, and may include at least one n-type impurity of P, As, Sb, or Bi.

Referring to FIGS. 1A,1B, 3, and 4, the semiconductor device 100 according to some embodiments may include a first gate line GL1 extending in the second direction D2 from the merged cell MLC and surrounding the first and second channel patterns 130A1 and 130B1, a second gate line GL2 extending in the second direction D2 from the first half-cell LC1 and surrounding the third channel patterns 130B2, and a third gate line GL3 extending in the second direction D2 from the second half-cell LC2 and surrounding the fourth channel patterns 130A2. The first to third gate lines GL1, GL2, and GL3 can be understood as a structure in which one gate line may be separated by a first isolation pattern SP1 (which may also be referred to as a first gate isolation pattern SP1) and a second isolation pattern SP2 (which may also be referred to as a second gate isolation pattern SP2). As illustrated in FIG. 1A and FIG. 4, the second and third gate lines GL2 and GL3 may overlap the first gate line GL1 in the second direction D2, and may be separated by the first isolation pattern SP1 and the second isolation pattern SP2, respectively. For example, the first isolation pattern SP1 may separate the first gate line GL1 from the second gate line GL2 between the merged cell MLC and the first half-cell LC1. As another example, the second isolation pattern SP2 may separate the first gate line GL1 from the third gate line GL3 between the merged cell MLC and the second half-cell LC2. It will be understood that “an element A surrounds an element B” (or similar language) as used herein means that the element A is at least partially around the element B but does not necessarily mean that the element A completely encloses the element B.

As illustrated in FIGS. 3 and 4, each of the first to third gate lines GL1, GL2, and GL3 may include a gate electrode 145 extending in the second direction D2 and surrounding each of the first to fourth channel patterns 130A1, 130B1, 130A2, and 130B2, a gate insulating film 142 disposed between the gate electrode 145 and the associated channel patterns 130A1, 130B1, 130A2, and 130B2, gate spacers 141 disposed on both (i.e., opposite) side surfaces of a portion of the gate electrode 145 located on the uppermost channel pattern, and a gate capping layer 147 disposed on the gate electrode 145 between the gate spacers 141.

The gate electrode 145 may include a conductive material. For example, the gate electrode 145 may include at least one of W, Ti, Ta, Mo, TiN, TaN, WN, TiON, TiAlC, TiAlN, or TaAlC. In some embodiments, the gate electrode 145 may include a semiconductor material, such as doped polysilicon. At least one of the gate electrodes 145 may include a multilayer structure formed of different materials.

The gate insulating film 142 may include a dielectric material. For example, the gate insulating film 142 may include an oxide, a nitride, or a high-κ material. The high-κ material refers to a dielectric material having a higher dielectric constant than a silicon oxide film (SiO₂), and the high-κ material may be, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). In some embodiments, the gate insulating film 142 may include two or more different dielectric films.

The gate spacers 141 may include an insulating material. For example, the gate spacers 141 may include at least one of silicon oxide, silicon nitride, or silicon oxynitride. In some embodiments, the gate spacers 141 may include a multilayer structure formed of different materials. The gate capping layer 147 may include, for example, silicon nitride, silicon oxynitride, silicon carbon nitride, or silicon oxycarbon nitride.

The first to third gate lines GL1, GL2, and GL3 according to some embodiments may include internal spacers IS. The internal spacers IS may be disposed on both (i.e., opposite) sides of the gate electrode portions 145S located between the first to fourth channel patterns 130A1, 130B1, 130B2, and 130A2, respectively. For example, the internal spacers IS may include a low-κ dielectric such as an oxide, a nitride, or an oxynitride. In some embodiments, gate electrode portions 145S may be surrounded by gate insulating film portions 142S in the first direction D1. The gate electrode portions 145S and the gate insulating film portions 142S may be spaced apart from the first to fourth source/drain patterns 120A1, 120B1, 120B2, and 120A2 by the internal spacers IS. In some embodiments, the internal spacers IS may have convex side surfaces toward the gate electrode portions 145S, but are not limited thereto. In some embodiments, the internal spacers IS may be applied only to a p-type transistor. For example, the internal spacers IS may be disposed on both sides of the gate electrode portions 145S located between the first and fourth channel patterns 130A1 and 130A2, respectively.

In this manner, the semiconductor device 100 according to some embodiments may be configured to include first and second conductivity type (e.g., first p-type and first n-type) transistors having extended channel widths in the merged cell MLC, a second conductivity type (e.g., second n-type) transistor in the first half-cell LC1, and a first conductivity type (e.g., second p-type) transistor in the second half-cell LC2.

The semiconductor device 100 according to some embodiments may further include a first interlayer insulating layer 151 disposed on the device isolation layer 110 to be on (e.g., to cover and/or overlap) the first to fourth source/drain patterns 120A1, 120B1, 120B2, and 120A2, as illustrated in FIGS. 3, 5A, and 5B, and a second interlayer insulating layer 152 on (e.g., covering and/or overlapping) the first to third gate lines GL1, GL2, and GL3 on the first interlayer insulating layer 151. For example, the first and second interlayer insulating layers 151 and 152 may include a spin-on hardmask (SOH), a flowable oxide (FOX), Tonen Silazen (TOSZ), undoped silica glass (USG), borosilica glass (BSG), phosphosilaca glass (PSG), borophosphoSilica glass (BPSG), plasma enhanced tetra ethyl ortho silicate (PETEOS), fluoride silicate glass (FSG), a high density plasma (HDP) oxide, a plasma enhanced oxide (PEOX), a flowable CVD (FCVD) oxide, or a combination thereof. The first and second interlayer insulating layers 151 and 152 may be formed using a chemical vapor deposition (CVD) process, a flowable CVD process, or a spin coating process, respectively.

The semiconductor device 100 according to some embodiments may include contact structures 180A, 180B, and 180AB connected to the first to fourth source/drain patterns 120A1, 120B1, 120B2, and 120A2 and penetrating (i.e., extending into) an interlayer insulating layer (e.g., the first and second interlayer insulating layers 151 and 152). The merged cell MLC may include a shared contact structure 180AB commonly connected to the first source/drain pattern 120A1 and the second source/drain pattern 120B1.

Each of the contact structures 180A, 180B, and 180AB may include a contact plug and a conductive barrier surrounding the contact plug. For example, the contact plug may include Cu, Co, Mo, Ru, W, or an alloy thereof. For example, the conductive barrier may include Ta, TaN, Mn, MnN, WN, Ti, TiN, or a combination thereof. In some embodiments, a metal-semiconductor compound layer may be disposed between the contact structure 180A, 180B, and 180AB and the first to fourth source/drain patterns 120A1, 120B1, 120B2, and 120A2, respectively. The metal-semiconductor compound layer may include a metal-silicide, for example, at least one of titanium-silicide, tantalum-silicide, tungsten-silicide, nickel-silicide, or cobalt-silicide.

Referring to FIG. 4, a gate contact GC may penetrate the second interlayer insulating layer 152 and the gate capping layer 147, and may be connected to the gate electrode 145.

Referring to FIGS. 1A, 1B, 3, 4, 5A, and 5B, the semiconductor device 100 according to some embodiments may include an interconnection structure 190. The interconnection structure 190 may be provided on a front side of the semiconductor device 100. The interconnection structure 190 may include first to fourth interconnection insulating layers 191, 192, 193, and 194, a first interconnection line M1 disposed within a second interconnection insulating layer 192, a first via (V1a and V1b) connected to the first interconnection line M1 by penetrating the first interconnection insulating layer 191, a second interconnection line M2 disposed in the fourth interconnection insulating layer 194, and a second via V2 connected to the second interconnection line M2 by penetrating the third interconnection insulating layer 193.

In some embodiments, the first interconnection line M1 and the first via (V1a and V1b), and the second interconnection line M2 and the second via V2 may be formed by a dual damascene process, respectively. For example, the first to fourth interconnection insulating layers 191, 192, 193, and 194 may include a low-κ material such as silicon oxide, silicon oxynitride, SiOC, or SiCOH. For example, the first and second interconnection lines M1 and M2 and the first via V1a and V1b may include copper or a copper-containing alloy.

The first interconnection line M1 may be connected to the contact structure (180A, 180AB, and 180B) and the gate contact GC by the first via (V1a and V1b), respectively. Similarly, the second interconnection line M2 may be connected to the first interconnection line M1 by the second via V2, respectively. The second interconnection line M2 may electrically connect the second n-type transistor of the first half-cell LC1 and the second p-type transistor of the second half-cell LC2, which may be spatially separated from each other by the merged cell MLC, to form a single CMOS circuit cell.

In some embodiments, the first interconnection line M1 may include the first and second power lines PL1 and PL2 supplying power to the merged cell MLC and the first and second half-cells LC1 and LC2, respectively. Referring to FIGS. 5A and 5B along with FIG. 1B, the first power line PL1 and the second power line PL2 supplying voltage to the merged cell MLC may be located on the first and second merged active patterns (AP1 and AP2), respectively. The first power line PL1 and the second power line PL2 supplying voltage to the CMOS circuit cell formed by combining the first and second half-cells (LC1 and LC2) may be respectively located on a lower boundary of the second half-cell LC2 and an upper boundary of the first half-cell LC1.

In this manner, when introducing a merged cell expanding an effective width of a channel pattern under scaling conditions of the semiconductor device, adjacent cell regions may have only a single type of active region (or active pattern), and may remain as dummy regions, but according to some embodiments, transistors of second and first conductivity types may be respectively implemented in remaining cell regions and electrically connected through an interconnection line (second interconnection line M2), such that they may be utilized as functional cells, and as a result, space loss due to introduction of the merged cell MLC may be prevented.

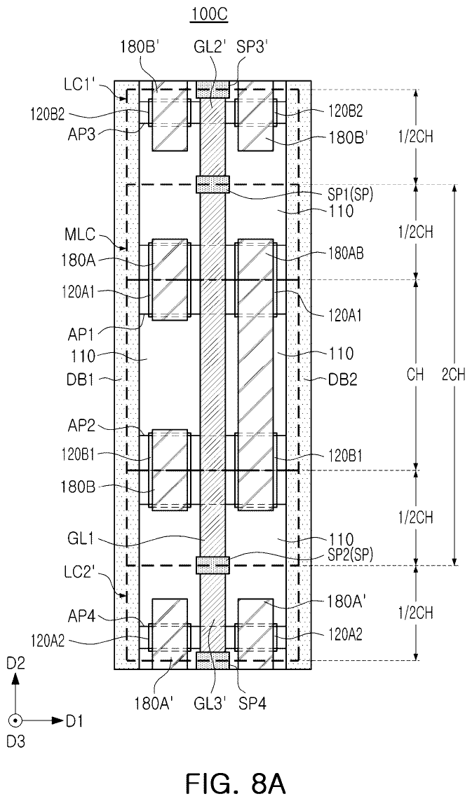

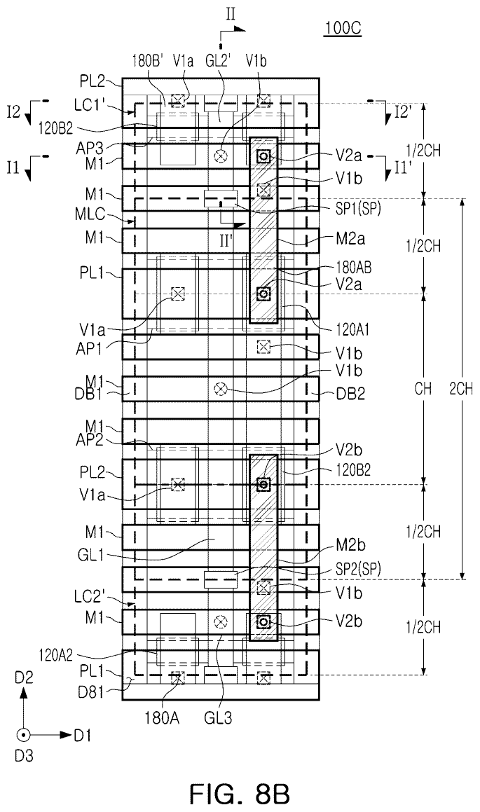

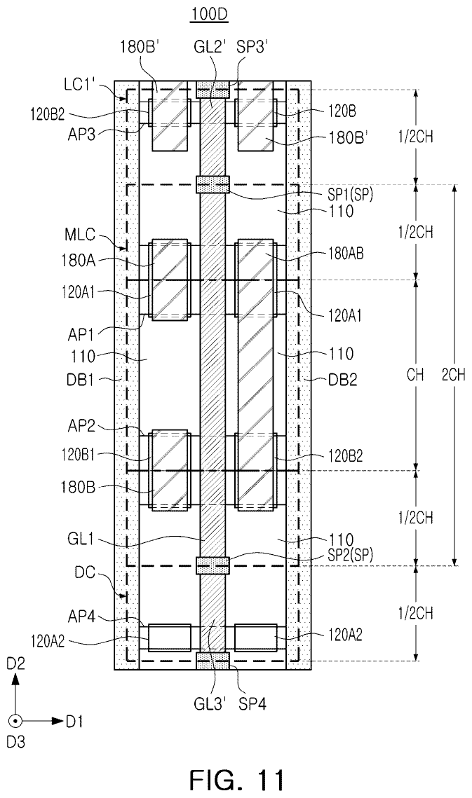

The semiconductor device according to example embodiments may be implemented in various manners. For example, the semiconductor device described above is illustrated as a form in which different types of transistors are implemented in each of remaining half-cells, but a capacitor having a metal-oxide semiconductor (MOS) structure may be implemented instead of the transistor (see FIGS. 8A to 10), and a logic circuit element such as a transistor or capacitor may be implemented only in at least one of the first and second half-cells (see FIG. 11).

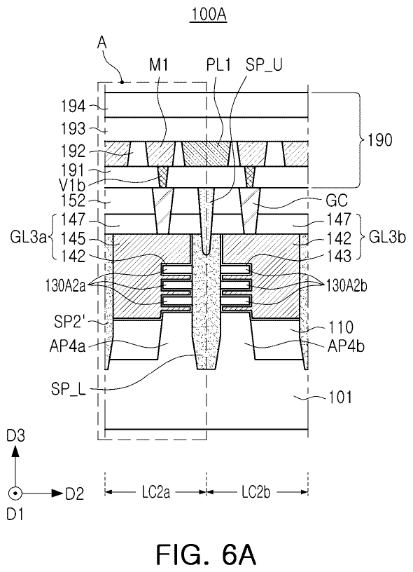

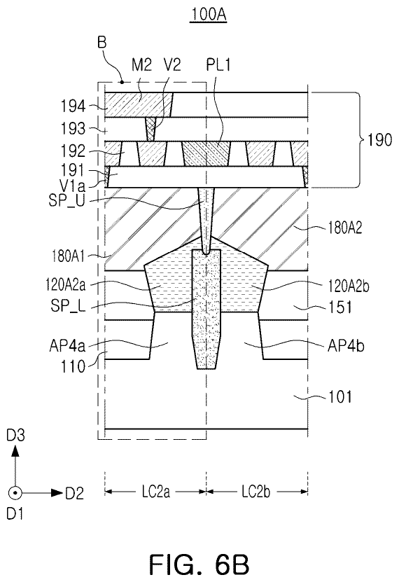

In addition, in the semiconductor device described above, only the first and second active patterns AP1 and AP2 of the merged cell MLC are illustrated as merged active patterns, but the third and fourth active patterns AP3 and AP4 of the first and second half-cells LC1 and LC2 may also be provided as a structure separated from the active pattern of a different cell LC2b adjacent in the second direction D2, as illustrated in FIGS. 6A and 6B.

FIGS. 6A and 6B are cross-sectional views illustrating a semiconductor device according to some embodiments. FIGS. 6A and 6B are cross-sectional views illustrating a region of the second half-cell LC2 of FIGS. 4 and 5A and other adjacent cells, respectively, where regions “A” and “B” in FIGS. 6A and 6B can be understood as regions corresponding to the second half-cell LC2 of FIGS. 4 and 5A. In other words, the region “A” in FIG. 6A can be understood as corresponding to the region “A” of the second half-cell LC2 of FIG. 4, and the region “B” in FIG. 6B can be understood as corresponding to the region “B” of the second half-cell LC2 of FIG. 5A.

A semiconductor device 100A according to some embodiments can be understood to have a structure similar to the semiconductor device 100 illustrated in FIGS. 1A, 1B, 2, 3, 4, 5A and 5B, except that an active pattern AP4 a of a second half-cell LC2a may be separated from an active pattern AP4b of a different cell LC2b, adjacent thereto, by an isolation pattern structure (SP_L and SP_U), as illustrated in FIGS. 6A and 6B. In addition, components of the semiconductor device 100A can be understood by referring to the description of the same or similar components of the semiconductor device 100 illustrated in FIGS. 1A, 1B, 2, 3, 4, 5A and 5B, unless otherwise specifically described.

As illustrated in FIGS. 6A and 6B, a lower isolation pattern SP_L may extend in the first direction D1 along a boundary between a second half-cell LC2a and a cell LC2b adjacent thereto, and may be disposed between two gate lines GL3a and GL3b, between two groups of channel patterns 130A2a and 130A2b, and between two active patterns AP4a and AP4b.

From a process perspective, the active pattern AP4a of the second half-cell LC2a may be a structure obtained by dividing one active pattern (see description of FIG. 2) merged with the active pattern AP4b of the same type (e.g., p-type) of a cell adjacent thereto by the lower isolation pattern SP_L. For example, the fourth active pattern AP4 (see FIG. 4) may be divided by the lower isolation pattern SP_L to obtain the active patterns AP4a and AP4b, although embodiments of the present disclosure are not limited thereto.

Similarly, the two groups of channel patterns 130A2a and 130A2b may be structures obtained by dividing relatively large-width channel patterns located on the merged active pattern by the lower isolation pattern SP_L. For example, the fourth channel patterns 130A2 (see FIG. 4) may be divided by the lower isolation pattern SP_L to obtain the two groups of channel patterns 130A2a and 130A2b, although embodiments of the present disclosure are not limited thereto. In some embodiments, a width of one group of channel patterns 130A2a may be substantially the same as a width of the other group of channel patterns 130A2b (e.g., in the second direction D2). In addition, the two gate lines GL3a and GL3b extended in the second direction D2 may also be structures obtained by dividing one gate line by the lower isolation pattern SP_L. For example, the third gate line GL3 (see FIG. 4) may be divided by the lower isolation pattern SP_L to obtain the two gate lines GL3a and GL3b, although embodiments of the present disclosure are not limited thereto.

Referring to FIG. 6B, a lower isolation pattern SP_L may extend in the first direction D1 to divide a source/drain pattern 120A2 (see FIG. 5A) into two source/drain patterns 120A2a and 120A2b. In some embodiments, upper regions of the two source/drain patterns 120A2a and 120A2b may be separated by an upper isolation pattern SP_U connected to the lower isolation pattern SP_L. The two separated source/drain patterns 120A2a and 120A2b may be respectively connected to two groups of channel patterns 130A2a and 130A2b.

Two contact structures 180A1 and 180A2 may be configured to be respectively connected to the two separated source/drain patterns 120A2a and 120A2b. The first and second contact structures 180A1 and 180A2 may be separated from each other by the upper isolation pattern SP_U to provide independent contact paths respectively connected to the source/drain patterns 120A2a and 120A2b. For example, a contact structure 180A (see FIG. 5A) may be divided by the upper isolation pattern SP_U to obtain the first and second contact structures 180A1 and 180A2, although embodiments of the present disclosure are not limited thereto.

Likewise, a fourth active pattern AP4 of a second half-cell LC2 (see FIG. 5A) may be separated into an active pattern AP4a of a different cell LC2a and an active pattern AP4b of a different cell LC2b adjacent in the second direction D2.

Similarly, a third active pattern AP3 of a first half-cell LC1 (see FIGS. 4 and 5A) may also be separated into active patterns of different cells adjacent in the second direction D2, similar to the second half-cell LC2.

In FIGS. 1A, 1B, 2, 3, 4, 5A, and 5B, it was illustrated that one merged cell MLC is disposed in parallel in the second direction D2 between the first and second half-cells LC1 and LC2, and that a width of the merged cell MLC (e.g., in the first direction D1) may be substantially the same as a width of each of the first and second half-cells LC1 and LC2 (e.g., in the first direction D1), but various other arrangements may be provided. For example, a plurality of merged cells may be disposed between the first and second half-cells LC1 and LC2 (e.g., in the second direction D2).

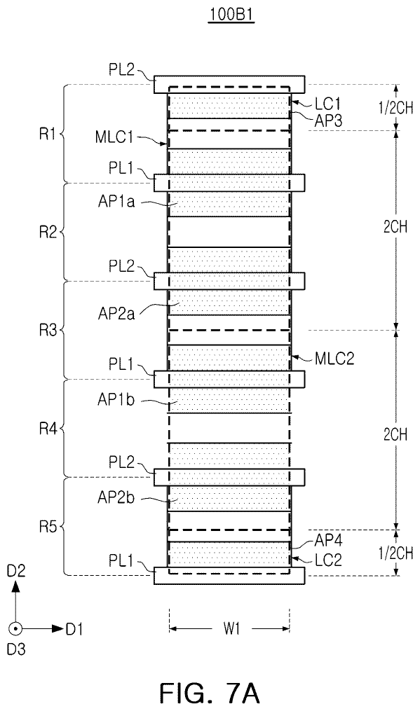

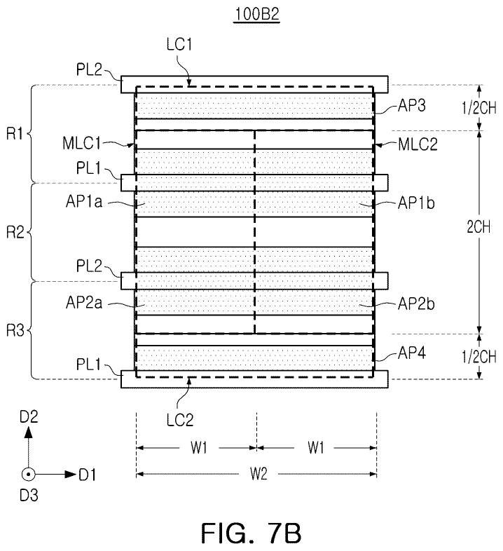

FIGS. 7A and 7B are schematic plan views illustrating a cell layout of a semiconductor device according to some embodiments.

First, referring to FIG. 7A, a semiconductor device 100B1 according to some embodiments can be understood to have a structure similar to that of the semiconductor device 100 illustrated in FIGS. 1A, 1B, 2, 3, 4, 5A and 5B, except that two merged cells disposed side by side in the second direction D2 between first and second half-cells LC1 and LC2 are included. In addition, components of the semiconductor device 100B1 can be understood by referring to description of the same or similar components of the semiconductor device 100 illustrated in FIGS. 1A, 1B, 2, 3, 4, 5A and 5B, unless otherwise specifically described.

The semiconductor device 100B1 according to some embodiments may include first and second merged cells MLC1 and MLC2 disposed in the second direction D2 between the first and second half-cells LC1 and LC2. For example, the first and second merged cells MLC1 and MLC2 may be adjacent to each other in the second direction D2. Each of the first and second merged cells MLC1 and MLC2 may include a first active pattern (AP1a and AP1b) and a second active pattern (AP2a and AP2b) having a relatively large width, and as described in FIGS. 1A and 1B, a first conductivity type (e.g., p-type) transistor may be formed on each of the first active patterns AP1a and AP1b, and a second conductivity type (e.g., n-type) transistor may be formed on each of the second active patterns AP2a and AP2b. Each of the first and second half-cells LC1 and LC2 may include one active pattern having a relatively small width. Specifically, the first and second half-cells LC1 and LC2 may include a third active pattern AP3 and a fourth active pattern AP4, respectively, and as described in FIGS. 1A and 1B, a second conductivity type (e.g., n-type) transistor may be formed on the third active pattern AP3, and a first conductivity type (e.g., p-type) transistor may be formed on the fourth active pattern AP4. A second conductivity type (e.g., n-type) transistor of the first half-cell LC1 and a first conductivity type (e.g., p-type) transistor of the second half-cell LC2 may be electrically connected to each other to provide a CMOS cell.

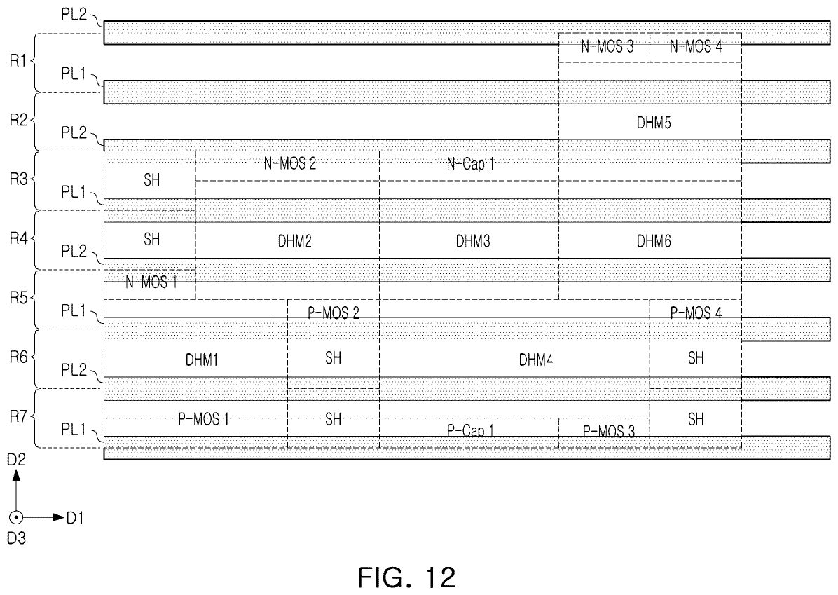

The first merged cell MLC1 and the second merged cell MLC2 may be disposed such that the first active pattern AP1b and the second active pattern AP2a may be adjacent to each other (e.g., in the second direction D2), the first half-cell LC1 may be disposed to be adjacent to the first active pattern AP1a of the first merged cell MLC1, and the second half-cell LC2 may be disposed to be adjacent to the second active pattern AP2b of the second merged cell MLC2. In some embodiments, in the first direction D1, the first and second merged cells MLC1 and MLC2 may have a width W1, equal to a width W1 of the first and second half-cells LC1 and LC2, respectively, but is not limited thereto, and in other embodiments may have different widths (e.g., see FIGS. 7B and 12).

Referring to FIG. 7B, a semiconductor device 100B2 according to some embodiments can be understood to have a similar structure to the semiconductor device 100 illustrated in FIGS. 1A, 1B, 2, 3, 4, 5A and 5B, except that two merged cells MLC1 and MLC2 disposed side by side in the first direction D1 between first and second half-cells LC1 and LC2 are included. In addition, components of the semiconductor device 100B2 can be understood by referring to description of the same or similar components of the semiconductor device 100 illustrated in FIGS. 1A, 1B, 2, 3, 4, 5A and 5B, unless otherwise specifically described.

The semiconductor device 100B2 according to some embodiments may include first and second merged cells MLC1 and MLC2 disposed in the first direction D1 between the first and second half-cells LC1 and LC2. For example, the first and second merged cells MLC1 and MLC2 may be adjacent to each other in the first direction D1. Each of the first and second merged cells MLC1 and MLC2 may include a first active pattern (AP1a and AP1b) and a second active pattern (AP2a and AP2b), similar to the semiconductor device 100B1 described above, and the first and second half-cells LC1 and LC2 may include a third active pattern AP3 and a fourth active pattern AP4, respectively. In some embodiments, the first merged cell MLC1 and the second merged cell MLC2 may be separated by an isolation structure similar to the first and second isolation structures (see DB1 and DB2 of FIG. 1A).

The first half-cell LC1 may be disposed adjacent to the first active patterns AP1a and AP1b of the first and second merged cells MLC1 and MLC2, and the second half-cell LC2 may be disposed adjacent to the second active patterns AP2a and AP2b of the first and second merged cells MLC1 and MLC2. In some embodiments, in the first direction D1, each of the first merged cell MLC1 and the second merged cell MLC2 may have a first width W1, and each of the first and second half-cells LC1 and LC2 may have a second width W2, corresponding to twice the first width W1, but is not limited thereto, and in other embodiments may have different widths (e.g., see FIGS. 7A and 12). In other words, in some embodiments, each of the first and second half-cells LC1 and LC2 may have a second width W2 in the first direction D1 that is different from a first width W1 of each of the first and second merged cells MLC1 and MLC2. In some embodiments, the second width W2 may be twice the first width W1 (i.e., the second width W2 may be two times greater than the first width W1).

The semiconductor devices described above are illustrated in which a different type of transistor was formed in each of the first and second half-cells LC1 and LC2 according to some embodiments, but in other embodiments (e.g., see FIGS. 8A to 11), at least one of the first and second half-cells LC1 and LC2 may include a logic circuit element such as a capacitor in addition to the transistor.

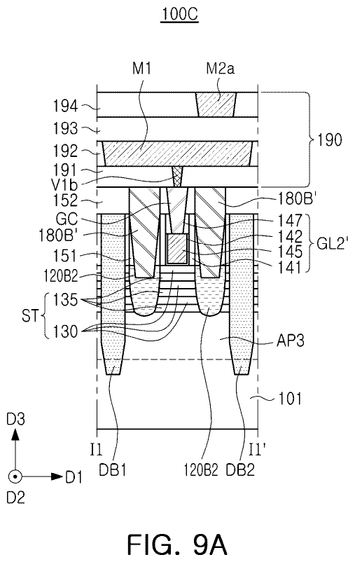

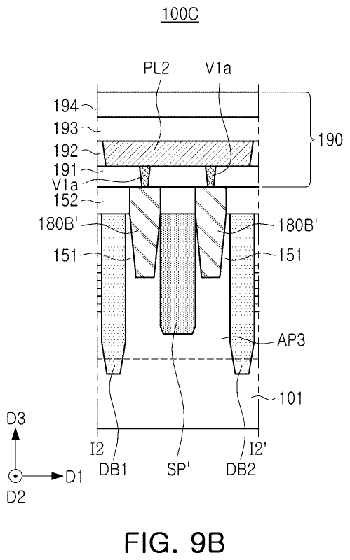

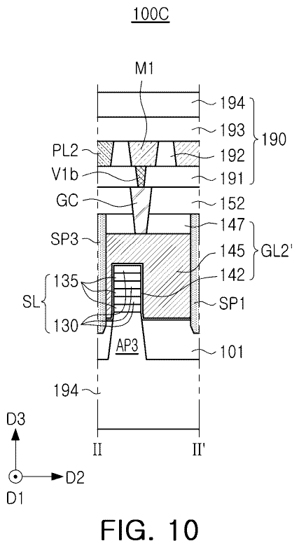

FIGS. 8A and 8B are plan views illustrating a semiconductor device according to some embodiments, and illustrate the semiconductor device before and after application of an interconnection structure, respectively. FIGS. 9A and 9B are cross-sectional views of the semiconductor device illustrated in FIG. 8B, taken along lines I1-I1′ and I2-I2′, respectively. FIG. 10 is a cross-sectional view of the semiconductor device illustrated in FIG. 8B, taken along line II-II′.

Referring to FIGS. 8A, 8B, 9A, 9B, and 10, a semiconductor device 100C according to some embodiments can be understood to have a structure similar to that of the semiconductor device 100 illustrated in FIGS. 1A, 1B, 2, 3, 4, 5A and 5B, except that a capacitor of a MOS structure is disposed instead of a transistor in first and second half-cells LC1′ and LC2′. In addition, components of the semiconductor device 100C can be understood by referring to description of the same or similar components of the semiconductor device 100 illustrated in FIGS. 1A, 1B, 2, 3, 4, 5A and 5B, unless otherwise specifically described.

The semiconductor device 100C according to some embodiments may include a capacitor of a MOS structure in each of the first and second half-cells LC1′ and LC2′. Referring to FIG. 9A, the capacitor of the first half-cell LC1′ may include a fin-type stack ST in which channel patterns 130 and sacrificial patterns 135 are alternately stacked on a third active pattern AP3 (e.g., in the third direction D3). For example, the channel patterns 130 may include Si, and the sacrificial patterns 135 may include SiGe.

In some embodiments, a second gate line GL2′ may extend in the second direction D2, and may be formed along upper and side surfaces of the fin-type stack ST. The second gate line GL2′ may include a gate insulating film 142 provided as a dielectric layer of the capacitor, and a gate electrode 145 provided as a first side electrode of the capacitor. The semiconductor device 100C may include epitaxial patterns 120B2 respectively connected to both (i.e., opposite) sides of the fin-type stack ST in the first direction D1, and contact structures 180B′ connected to the epitaxial patterns 120B2 may serve as second side electrodes of the capacitor. In other words, the gate electrode 145 may provide a first electrode of the capacitor, the contact structures 180B′ may provide second electrode(s) of the capacitor, and the gate insulating film 142 may provide the dielectric layer of the capacitor and may be between the gate electrode 145 and the contact structures 180B′ (e.g., in the first direction D1). Since the epitaxial patterns 120B2 may be commonly connected to the same electrode structure (e.g., second power line PL2), as illustrated in FIGS. 8A, 9A, and 9B, the contact structures 180B′ may have substantially the same lengths extended in the first direction D1. The epitaxial patterns 120B2 may include a second conductivity type (e.g., n-type) epitaxial pattern, identical to the third source/drain pattern 120B2 of FIG. 1A.

Referring to FIGS. 8B and 9A, in the first half-cell LC1′, the gate contact GC, which may be a first side electrode of a capacitor of a MOS structure (e.g., along with the gate electrode 145), may be connected to a first interconnection line M1 through a gate via V1b. Referring to FIGS. 8B and 9B, in the first half-cell LC1′, two contact structures 180B′, which may be second side electrodes of the capacitor of the MOS structure, may be commonly connected to a second power line PL2 through a different first via V1a. In some embodiments, the capacitor of the first half-cell LC1′ may be connected to a first conductivity type transistor of a merged cell MLC through a second interconnection line M2a and a second via V2a (e.g., see FIG. 8B).

Similarly, the second half-cell LC2′ may also include a capacitor of a MOS structure on a fourth active pattern AP4, similar to the first half-cell LC1′. Epitaxial patterns of the second half-cell LC2′ may include the same first conductivity type (e.g., p-type) epitaxial patterns as the fourth source/drain patterns 120A2 of FIG. 1A. The capacitor of the second half-cell LC2′ may be connected to a second conductivity type transistor of the merged cell MLC through another second interconnection line M2b and another second via V2b (e.g., see FIG. 8B).

The semiconductor device 100C according to example embodiments is not limited to the interconnection structure 190 illustrated in FIGS. 8B, 9A, 9B, and 10, and interconnection connection of the capacitors of the first and second half-cells LC1′ and LC2′ and interconnection connection with the merged cell MLC may be variously changed.

As mentioned above, a transistor and a capacitor may not be disposed in both first and second half-cells on both sides of a merged cell, and as illustrated in FIG. 11, a transistor or a capacitor may be disposed in only one of the first and second half-cells according to some embodiments. FIG. 11 is a schematic plan view illustrating a semiconductor device according to some embodiments, and can be understood as a cell layout, similar to FIG. 8A (before application of the interconnection structure).

Referring to FIG. 11, a semiconductor device 100D according to some embodiments may include a first half-cell LC1′, a dummy cell DC, and a merged cell MLC between the first half-cell LC1′ and the dummy cell DC, as a cell layout corresponding to FIG. 8A. The merged cell MLC and the first half-cell LC1′ may include configurations corresponding to the merged cell MLC and the first half-cell LC1′ of the semiconductor device 100C illustrated in FIG. 8A. The dummy cell DC according to some embodiments may be provided as a dummy region, unlike the second half-cell LC2′ of FIG. 8A. In some embodiments, as shown in FIG. 11, the dummy cell DC is illustrated in a form in which only a contact structure is omitted, but in other embodiments, source/drain patterns 120A2 may also be omitted from the dummy cell DC. In addition, a third gate line GL3′ may remain in the dummy cell DC as a dummy gate structure according to some embodiments.

According to some embodiments, as described above, at least one merged cell MLC may be disposed in the second direction D2 between the first and second half-cells LC1 (LC1′) and LC2 (LC2′) in a parallel manner (or between one of the first and second half-cells LC1 (LC1′) and LC2 (LC2′) and the dummy cell DC), but it will be understood that the present disclosure is not limited thereto and the merged cell may be disposed in various forms between the first and second half-cells. In some embodiments, the merged cell may have a width (e.g., in the first direction D1 or the second direction D2), different from a width of at least one of the first and second half-cells, and in some embodiments, the merged cell may be disposed such that only a portion of the merged cell overlaps at least one of the first and second half-cells.

FIG. 12 is a schematic plan view illustrating a cell layout of a semiconductor device according to some embodiments. In particular, FIG. 12 illustrates a cell layout of a merged cell and first and second half-cells of the semiconductor device having various arrangements.

Referring to FIG. 12, cells of various forms may be disposed in alignment according to a plurality of rows R1 to R7. A first power line PL1 and a second power line PL2, supplying voltage to each of the cells, may be formed at a boundary of each of the plurality of rows R1 to R7, and the first power line PL1 and the second power line PL2 may extend in the first direction D1, and may be alternately disposed in the second direction D2. For example, the first power line PL1 and the second power line PL2 may be provided as VDD (e.g., a drain voltage) and VSS (e.g., a source voltage), respectively, and may be disposed at a ratio of 1:1.

A plurality of rows R1, R2, R3, R4, R5, R6, and R7 may be disposed to have the same height (e.g., in the second direction D2), and the plurality of rows R1 to R7 may define a height of a basic cell, and a portion of the cells may be disposed across the plurality of rows.

Still referring to FIG. 12, a basic cell SH may be a single height cell disposed in one row, and first to sixth merged cells DHM1 to DHM6 may include an active pattern merged with the same type of active pattern of two adjacent rows, similar to the merged cell MLC described above, and may include adjacent regions (e.g., half regions) of two adjacent rows. Each of the first to sixth merged cells DHM1 to DHM6 may have a height twice a cell height of the basic cell SH (e.g., in the second direction D2).

A pair of half-cells may be disposed at upper and lower boundaries of each of the first to sixth merged cells DHM1 to DHM6. In some embodiments, five pairs of half-cells may include remaining regions (unmerged regions) of the first to sixth merged cells DHM1 to DHM6 or a combination thereof and the other two rows adjacent thereto, respectively, and may have a height of half the cell height of the basic cell SH (e.g., in the second direction D2).

Some pairs of half-cells may include an n-type transistor (e.g., an NMOS) and a p-type transistor (e.g., a PMOS), respectively (see FIGS. 1A and 1B), and some pairs of half-cells may include an n-MOS structured capacitor (n-Cap) and a p-MOS structured capacitor (p-Cap), respectively (see FIGS. 8A and 8B).

The half-cells according to some embodiments may have a width (e.g., in the first direction D1), different from a width of the related merged cells DHM1 to DHM6, or some of the half-cells may have different widths in the same pair. In addition, a plurality of merged cells may be disposed between some of the half-cells. As illustrated in FIG. 12, the merged cell and the pair of half-cells according to some embodiments may be disposed in various forms.

Still referring to FIG. 12, the first merged cell DHM1 may be disposed between a first pair of half-cells N-MOS 1 and P-MOS 1. A second half-cell P-MOS 1 may have a width (e.g., in the first direction D1) corresponding to a width of the first merged cell DHM1, and a first half-cell N-MOS 1 may have a width (e.g., in the first direction D1), smaller than the width of the second half-cell P-MOS 1.

The second merged cell DHM2 may be disposed between a second pair of half-cells N-MOS 2 and P-MOS 2. A first half-cell N-MOS 2 may have a width (e.g., in the first direction D1) corresponding to a width of the second merged cell DHM2, and a second half-cell P-MOS 2 may have a width (e.g., in the first direction D1), smaller than the width of the first half-cell N-MOS 2.

Between a third pair of half-cells N-Cap 1 and P-Cap 1, similar to the semiconductor device 100B1 illustrated in FIG. 7A, the third merged cell DHM3 and the fourth merged cell DHM4 may be disposed in the second direction D2. The fourth merged cell DHM4 may have a width (e.g., in the first direction D1), greater than a width of the third merged cell DHM3. A first half-cell N-Cap 1 and a second half-cell P-Cap 1 may have widths (e.g., in the first direction D1) corresponding to the width of the third merged cell DHM3.

Similarly, between a fourth pair of half-cells N-MOS 3 and P-MOS 3, the fifth and sixth merged cells DHM5 and DHM6 and the fourth merged cell DHM4 may be disposed in the second direction D2. A width of each of the fifth and sixth merged cells DHM5 and DHM6 (e.g., in the first direction D1) may be smaller than a width of the fourth merged cell DHM4. Two first half-cells N-MOS 3 and N-MOS 4 may be disposed at an upper boundary of the fifth merged cell DHM5 in the first direction D1, a second half-cell P-MOS 3 may be disposed in parallel with the second half-cell P-Cap 1 at a lower boundary of the fourth merged cell DHM4, and a second half-cell P-MOS 4 may be disposed at a lower boundary of the sixth merged cell DHM6.

In this manner, the merged cell and the first and second half-cells may be disposed in various arrangements. It will be understood that any of the semiconductor devices 100, 100A, 100B1, 100B 2, 100C, 100D described above may be modified to have one or more of the arrangements of the merged cells and the first and second half-cells of FIG. 12.

According to the above-described example embodiments, at least one of adjacent cell regions of merged cells for expanding a channel width may not be left as a dummy region, but may be utilized as a functional cell region of a logic circuit such as a transistor or a capacitor, thereby reducing space loss.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, “third”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure. Further, as used herein, the term “and/or” includes any and all combinations of one or more of the associated listed items.

While example embodiments have been illustrated and described above, it will be apparent to those skilled in the art that modifications and variations can be made without departing from the scope of the present disclosure as defined by the appended claims.

What is claimed is:

1. A semiconductor device comprising:
a merged cell including a first active pattern and a second active pattern extending in a first direction and spaced apart from each other in a second direction intersecting the first direction, the merged cell further including a first p-type transistor on the first active pattern and a first n-type transistor on the second active pattern;
a first half-cell adjacent to the first active pattern of the merged cell in the second direction and including a third active pattern extending in the first direction;
a second half-cell adjacent to the second active pattern of the merged cell in the second direction and including a fourth active pattern extending in the first direction; and
a logic circuit element on at least one of the third active pattern or the fourth active pattern,
wherein the merged cell has a first cell height in the second direction, and the first and second half-cells each have a second cell height in the second direction that is less than the first cell height, and
wherein each of the first and second active patterns has a first width in the second direction, and each of the third and fourth active patterns has a second width in the second direction that is less than the first width.

2. The semiconductor device of claim 1, wherein the first cell height is four times greater than the second cell height.

3. The semiconductor device of claim 1, wherein the first width is more than twice the second width.

4. The semiconductor device of claim 1, wherein the first p-type transistor includes first channel patterns spaced apart from each other and stacked on the first active pattern in a third direction intersecting the first and second directions, and first p-type source/drain patterns on the first active pattern and electrically connected to opposite sides, respectively, of the first channel patterns in the first direction,
wherein the first n-type transistor includes second channel patterns spaced apart from each other and stacked on the second active pattern in the third direction, and first n-type source/drain patterns on the second active pattern and electrically connected to opposite sides, respectively, of the second channel patterns in the first direction, and
wherein the merged cell further includes a first gate line extending across the first and second active patterns in the second direction and at least partially surrounding each of the first and second channel patterns.

5. The semiconductor device of claim 4, wherein the logic circuit element includes at least one of a second n-type transistor on the third active pattern or a second p-type transistor on the fourth active pattern.

6. The semiconductor device of claim 5, wherein the logic circuit element includes the second n-type transistor on the third active pattern,
wherein the second n-type transistor includes third channel patterns stacked in the third direction and spaced apart from each other on the third active pattern, second n-type source/drain patterns on the third active pattern and electrically connected to opposite sides, respectively, of the third channel patterns in the first direction, and a second gate line extending across the third active pattern and at least partially surrounding each of the third channel patterns, and
wherein the semiconductor device further comprises a first gate isolation pattern that separates the first gate line from the second gate line between the merged cell and the first half-cell.

7. The semiconductor device of claim 5, wherein the logic circuit element includes the second p-type transistor on the fourth active pattern,
wherein the second p-type transistor includes fourth channel patterns stacked in the third direction and spaced apart from each other on the fourth active pattern, second p-type source/drain patterns on the fourth active pattern and electrically connected to opposite sides, respectively, of the fourth channel patterns in the first direction, and a third gate line extending across the fourth active pattern and at least partially surrounding each of the fourth channel patterns, and
wherein the semiconductor device further comprises a second gate isolation pattern that separates the first gate line from the third gate line between the merged cell and the second half-cell.

8. The semiconductor device of claim 1, wherein the logic circuit element includes a second n-type transistor on the third active pattern and a second p-type transistor on the fourth active pattern.

9. The semiconductor device of claim 8, further comprising an interconnection line electrically connecting the second n-type transistor to the second p-type transistor and extending in the second direction.

10. The semiconductor device of claim 1, wherein the logic circuit element includes a capacitor on at least one of the third active pattern or the fourth active pattern.

11. The semiconductor device of claim 1, wherein the merged cell has a width in the first direction that is equal to a width of each of the first and second half-cells in the first direction.

12. The semiconductor device of claim 1, wherein at least one of the first half-cell or the second half-cell has a width in the first direction that is different from a width of the merged cell in the first direction.

13. The semiconductor device of claim 1, wherein at least one of the first half-cell or the second half-cell includes a plurality of half-cells adjacent to a boundary of the merged cell.

14. The semiconductor device of claim 1, wherein the merged cell includes first and second merged cells that are adjacent to each other in the second direction and are between the first half-cell and the second half-cell,
wherein each of the first and second merged cells includes the first and second active patterns, and
wherein the first half-cell is adjacent to the first active pattern of the first merged cell, and the second half-cell is adjacent to the second active pattern of the second merged cell.

15. The semiconductor device of claim 1, wherein the merged cell includes first and second merged cells that are adjacent to each other in the first direction and are between the first half-cell and the second half-cell, and
wherein the first half-cell is adjacent to the first active pattern of the first and second merged cells, and the second half-cell is adjacent to the second active pattern of the first and second merged cells.

16. A semiconductor device comprising:
first to third rows each including a first conductivity type active pattern and a second conductivity type active pattern extending in a first direction and arranged in a second direction intersecting the first direction, wherein the first and second conductivity type active patterns of the second row are adjacent to the first conductivity type active pattern of the first row and the second conductivity type active pattern of the third row, respectively;
a merged cell in the second row and extending in a first region of each of the first and third rows adjacent to the second row, the merged cell including a first merged active pattern in which the first conductivity type active patterns of the first and second rows are merged, and a second merged active pattern in which the second conductivity type active patterns of the second and third rows are merged;
a first half-cell overlapping the merged cell in the second direction and extending in a second region of the first row, the first half-cell including the second conductivity type active pattern of the first row; and
a second half-cell overlapping the merged cell in the second direction and extending in a second region of the third row, the second half-cell including the first conductivity type active pattern of the third row,
wherein the merged cell includes a first conductivity type transistor on the first merged active pattern and a second conductivity type transistor on the second merged active pattern, and
wherein at least one of the first half-cell or the second half-cell includes a transistor or a capacitor on the second conductivity type active pattern of the first row or the first conductivity type active pattern of the third row.

17. The semiconductor device of claim 16, wherein the first to third rows each have a same row height in the second direction, and
wherein the merged cell has a first cell height in the second direction that is twice the row height, and the first and second half-cells have a second cell height and a third cell height in the second direction, respectively, that are half the row height.

18. The semiconductor device of claim 16, wherein a width of each of the first and second merged active patterns in the second direction is more than twice a width of each of the first conductivity type active pattern of the third row and the second conductivity type active pattern of the first row in the second direction.

19. A semiconductor device comprising:
a merged cell including a first active pattern and a second active pattern extending in a first direction and spaced apart from each other in a second direction intersecting the first direction, the merged cell further including a first p-type transistor on the first active pattern and a first n-type transistor on the second active pattern;
a first half-cell adjacent to the first active pattern of the merged cell in the second direction and including a third active pattern extending in the first direction, the first half-cell further including a second n-type transistor on the third active pattern; and
a second half-cell adjacent to the second active pattern of the merged cell in the second direction and including a fourth active pattern extending in the first direction, the second half-cell further including a second p-type transistor on the fourth active pattern,
wherein the merged cell has a first cell height in the second direction, and the first and second half-cells each have a second cell height in the second direction that is less than the first cell height, and
wherein each of the first and second active patterns has a first width in the second direction, and each of the third and fourth active patterns has a second width in the second direction that is less than the first width.

20. The semiconductor device of claim 19, wherein the merged cell further includes a first gate line crossing the first and second active patterns and extending in the second direction,
wherein the first half-cell further includes a second gate line crossing the third active pattern and extending in the second direction,
wherein the second half-cell further includes a third gate line crossing the fourth active pattern and extending in the second direction, and
wherein the semiconductor device further comprises a first gate isolation pattern that separates the first gate line from the second gate line between the merged cell and the first half-cell, and a second gate isolation pattern that separates the first gate line from the third gate line between the merged cell and the second half-cell.
